(19) United States
(12) Patent Application Publication
(10) Pub. No.: US 2026/0090441 A1
(43) Pub. Date: Mar. 26, 2026

(54) CHIP PACKAGE DEVICE

(71) Applicant: STMICROELECTRONICS INTERNATIONAL N.V., Geneva (CH)

(72) Inventors: Ludovic FALLOURD, Louans (FR); Gregoire DELACOURT, Tours (FR); Benjamin JOREZ, Charentilly (FR)

(21) Appl. No.: 19/324,484

(22) Filed: Sep. 10, 2025

(30) Foreign Application Priority Data
Sep. 24, 2024 (FR) 2410148

(51) Int. Cl. H01L 23/00

(52) U.S. Cl. CPC H10W 72/20; H10W 72/072; H10W 72/90; H10W 72/01212; H10W 72/07236; H10W 72/234; H10W 72/252; H10W 72/29; H10W 90/724

(57) ABSTRACT

The present disclosure provides a chip package device. An example chip package device includes: at least one connection pad on a first surface of the chip; at least one pillar extending from, and in contact with, the pad; the pillar being formed in an alloy of a first element and of a second element, a melting temperature of the alloy being greater than a melting temperature of at least one of the first and second elements and greater than 260° C.

### CROSS REFERENCE TO RELATED APPLICATION(S)

This application claims the priority benefit of French Patent Application Number FR2410148, filed on Sep. 24, 2024, entitled “Dispositif à puce conditionnée”, which is hereby incorporated by reference to the maximum extent allowable by law.

### TECHNICAL FIELD

The present disclosure relates generally to chip package devices and their related method of manufacturing.

### BACKGROUND

Chip package devices, such as Flip-chip devices, are essentially made of a chip which is coupled to a substrate having conducting pads. Usually, spherical solder bumps which melt below 250° C., or copper pillar with solder cap, are used to connect the chip to the pads.

Solder bumps can have some limitations with a pitch reduction which tends to a higher integration density. For a defined pitch, this solution has also a limited achievable height as it has a sphere shape.

### BRIEF SUMMARY

There is a need to provide a chip package device which is compatible with a pitch reduction and higher integration density at reasonable costs.

There is moreover a need to provide a chip package device which is compatible with the automotive circuits inspection requirements.

One embodiment addresses all or some of the drawbacks of known chip package devices.

One embodiment provides a chip package device comprising:
at least one connection pad on a first surface of the chip;
at least one pillar extending from, and in contact with, said pad;
   said pillar being formed in an alloy of a first element and of a second element, a melting temperature of said alloy being greater than a melting temperature of at least one of the first and second elements and greater than 260° C.

One embodiment provides a method of manufacturing a chip package device, comprising:
forming the chip of the chip package device, the chip having at least one connection pad on a first surface;
forming at least one pillar extending from, and in contact with, said pad, and formed in an alloy of a first element and of a second element,
   a melting temperature of said alloy being greater than a melting temperature of at least one of the first and second elements and greater than 260° C.

According to an embodiment, a ratio between a longitudinal extension of the pillar over its width is greater than 0.4.

According to an embodiment, said ratio is greater than 1, preferably superior to 2.

According to an embodiment, the longitudinal extension of the pillar describes an angle with an absolute value between 15° and 80° or between 100° and 165° as compared to a surface of the pad.

According to an embodiment, the formation of said pillar comprises:
a first step comprising a deposition of a first amount of a first material, formed with particles of the first element and particles of the second element, in contact with the pad;
a second step comprising a temperature treatment configured to form said alloy.

According to an embodiment, the formation of said pillar comprises:
a third step comprising a deposition of a second amount of the first material, in contact with all or parts of a top surface of the temperature treated first amount; and
a fourth step comprising a temperature treatment configured to form said alloy;
   third and fourth steps being repeatable.

According to an embodiment, at least first and second steps are performed on a wafer scale.

According to an embodiment, the first element is Sn, and the second element is among Cu, Ag or Au.

According to an embodiment, an insulating material is arranged around all or parts of lateral surfaces of the pillar.

According to an embodiment, the insulating material surrounds all the packaged chip device.

According to an embodiment, the insulating material is absent on lateral surfaces of the pillar facing outwards.

According to an embodiment, said lateral surfaces of the pillar facing outwards are grinded or cut.

According to an embodiment, the melting temperature of said alloy is greater than a reflow temperature profile defined by JEDEC.

One embodiment provides a circuit assembly comprising:
the chip package device as described above;
a printed circuit board comprising at least one connection pad whose surface imprint as seen in top view is larger than the chip; and
a solder material, having a melting temperature inferior to 260° C., and forming a meniscus between the lateral surface of the pillar facing outwards and said pad of the printed circuit board.

One embodiment provides a method of using a chip package device as described above, comprising:
soldering the pillar to at least one connection pad of a printed circuit board by using a solder material having a melting temperature inferior to 260° C.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates a chip package device assembly according to an embodiment;

FIG. 2 illustrates a chip package device manufacturing method according to an embodiment;

FIG. 3 illustrates a chip package device manufacturing method according to an embodiment;

FIG. 4 illustrates a chip package device manufacturing method according to an embodiment;

FIG. 5 illustrates a chip package device assembly according to an embodiment; and

FIG. 6 illustrates a heat flow graph versus temperature.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10% or 10°, and preferably within 5% or 5°.

Chip package devices, such as Flip-chip devices, or Wafer Level Chip Scale Packaging (WLCSP) devices or module devices, are devices, such as semiconductor circuits, integrated circuits chips, passive circuits or microelectromechanical systems, comprising external interconnects, on only one side, for connection to a receiving substrate, or circuit, comprising conducting pads. These external interconnects are usually made of solder bumps with the shape of balls and with a melting temperature below 250° C. The soldering temperatures and methods are usually following standards such as defined by JEDEC (Joint Electron Device Engineering Council).

Due to the ball shape of the bumps, the integration density is limited horizontally. The interconnection height is also limited. Another drawback of this solution is that the solder can be remolten in a case of a reflow over the melting temperature as during Flip-chip assembly for example.

In the sake of increasing integration density or increasing interconnection height, electroplated pillars have been developed. Nevertheless, this solution is costly.

The described embodiments provide a chip package device comprising:
at least one connection pad on a first surface of the chip;
at least one pillar extending from, and in contact with, said pad;
   said pillar being formed in an alloy of a first element and of a second element, a melting temperature of said alloy being greater than a melting temperature of at least one of the first and second elements and greater than 260° C., otherwise said, greater than reflow profile defined by JEDEC.

This allows a lower manufacturing cost for example as compared to electroplated copper pillars. Moreover, the obtained interconnections will not undergo melting in case of a reflow which renders the device more robust.

Depending of die design and final product purpose, this solution can also provide interconnects with flanks that can be wetted by a solder without additional finishing and without melting risks during final circuit assembly.

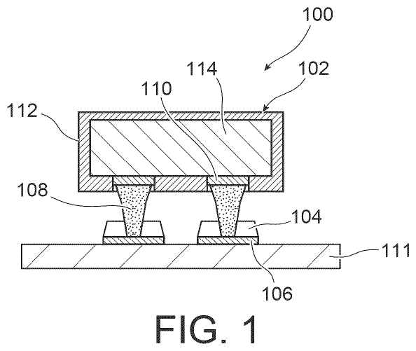

FIG. 1 illustrates a chip package assembly 100 according to an embodiment.

The chip package assembly 100 comprises a chip package device 102. The chip package device 102, which is for example a Flip-chip device, or a Wafer Level Chip Scale Packaging (WLCSP) device, a module device, or a leadless device, comprises for example a semiconductor circuit 114, an integrated circuit chip 114, a passive circuit or a microelectromechanical system. In the represented example, two external pads 110 of the chip package device are arranged on the lower surface of the chip 114. In an example, the number of pads can be from one to hundreds or even thousands. Pillars 108 are extending from, and in contact with, the pads 110. The pillars 108 are for example formed with a transient liquid phase sintering (TLPS) in an intermetallic alloy of a first element and of a second element. In the text, the terms alloy or intermetallic alloy are similar. The first element is for example among Sn or In, and the second element is for example among Cu, Ag or Au. The alloy formed is for example an intermetallic alloy, such as a SnCu alloy or an AuSn alloy. The melting temperature of the intermetallic alloy is greater than a melting temperature of at least one of the first and second elements and greater than 260° C. or greater than the reflow profile defined by JEDEC. In an example, the melting temperature of the alloy is greater than 350° C.

In an example, the alloy is formed while the chip is oriented at 180° from the orientation shown in FIG. 1, i.e. with pads 110 oriented toward the top. The alloy is obtained by melting a mix of the first and second elements at a temperature above 210° C. and below 260° C. depending on the mix proportion and particle size, for example about 219° C. for a mix comprising Sn and Cu. This mix may also contain a flux for reduction purpose. In the mix, the first and second elements are for example in a form of micro or nanoparticles, for example having a global spherical shape.

The mix can be deposited on the pads 110 by screen printing, or by dispensing, for example prior to the melting step.

Once the melting step is achieved, since the alloy has been formed, it will not be molten again even if a second melting step is applied to the chip. The alloy formed will also advantageously keep its shapes without collapsing into a sphere shape, compared to usual solder alloys, thus providing a suitable support for another cycle of mix deposition/melting treatment on top of the previously obtained alloy. It allows to obtain several stacked layers of the alloy which together form the pillars 108.

The final height of the obtained pillars 108 is for example of tenth of microns or even hundreds of microns. In an example, an aspect ratio between a longitudinal extension of the pillar, i.e. its height, over its width is greater than 0.4, for example greater than 1, preferably greater than 2. This aspect ratio is greater than an aspect ratio feasible with a traditional SnAgCu alloy (SAC) solder bump. This solution provides a precisely controllable stand-off distance, i.e. the distance between the chip package device and the substrate 111.

In the represented example, the chip 114 is covered on each of its external surfaces of an optional insulating or protecting material 112 which is for example a resin, a molding resin or a polymer. In the represented example, the material 112 does not cover the pillars 108.

In the example of FIG. 1, the pillars 108 are connected to pads 106 of a substrate 111 which is for example a printed circuit board. A solder material 104 connects a region of the pillars to the respective pad 106. In an example, the melting temperature of the solder material 104 is strictly inferior to 260° C., for example 217° C. or a temperature as defined by JEDEC standards. The solder material 104 is for example an SnAgCu alloy (SAC).

In an example, the surface imprint of the pads 106, as seen in top view, is larger than the chip. This helps for optical inspection.

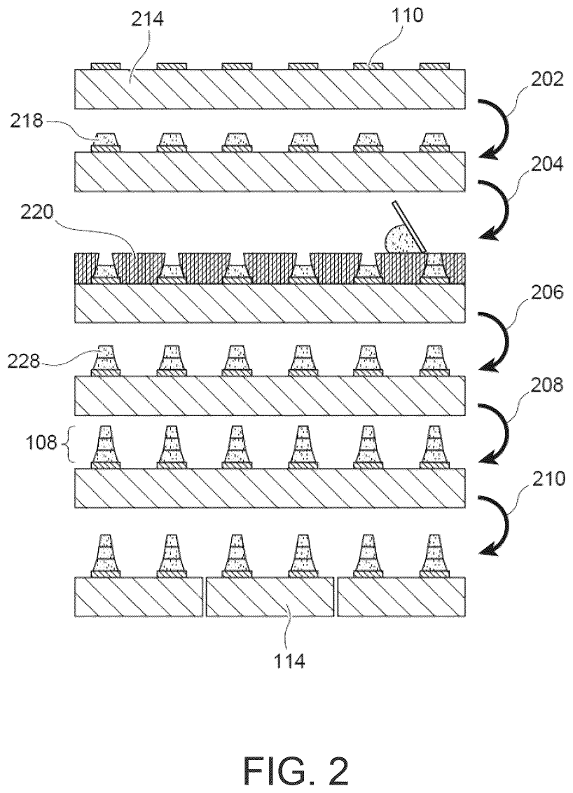

FIG. 2 illustrates a chip package device manufacturing method according to an embodiment.

In a first stage, chips similar to the chip 114 are manufactured for example in a silicon wafer 214. The connection pads 110 of the chips are oriented toward the top.

In a step 202, a first amount 218 of the alloy is formed on top of each of the pads. To do so, a non-illustrated resin or a mask having apertures aligned with the pads, is deposited on the substrate top surface. In an example, a layer of the mix comprising the first and second elements is deposited onto the mask and a squeegee swipes the mask surface to remove the mix surplus. Serigraphy, dispensing or jetting methods can also be applied. After the mix deposition, the mask is removed. Then a first temperature treatment, targeting for example between 230° C. and 250° C., or within JEDEC reflow profiles, is applied to obtain the alloy. In an example, the first temperature treatment is applied after the mask removal or before the mask removal. Once the first alloy amount is formed, it keeps its shape which is for example the shape of the apertures of the mask, thanks to a material having low slump properties.

In a step 204, following the step 202, another mask 220, for example made of the same material as the mask used in step 202 but with a greater thickness, is deposited on top of the substrate 214 and with apertures aligned with first alloy amounts 218 obtained at step 202. A second amount of the mix of the first and second elements is deposited in each of the apertures of the mask using for example a stencil as illustrated. A second temperature treatment, for example similar to the first temperature treatment, is performed prior or after the mask 220 removal. Since the first alloy amount does not melt under at least 260° C., it constitutes a stable base for the second amount formed on its top. During the second temperature treatment, the first and second alloy amounts become electrically connected for example by diffusion or soldering. The second alloy amount obtained keeps its shape which is for example the shape of the apertures of the mask 220.

In a further step 206, the mask 220 is removed for example mechanically or chemically. In another example, a stencil can be used and, in this case, it has to be withdrawn before reflow.

In a further step 208, a third alloy amount is formed, for example in the same way as for the second amount, on the top of the second amount. The second and third alloy amounts become connected electrically during the third temperature treatment. The first, second and third alloy amounts form the pillars 108. In the example of FIG. 2, only three amounts are stacked but the number of stacked alloy amounts can be between one and ten for example.

The apertures of the different masks can have similar or different shapes. In an example, the apertures of the first mask are larger than the apertures of the second mask, and the apertures of the second mask are larger than the apertures of the third mask.

In a further step 210, the different chips 114 are singulated. A pick-and-place process may then be performed.

In a non-illustrated step, an insulating material, for example a resin, a polymer or a molding material, is formed around the chip 114 and in between the pillars 108.

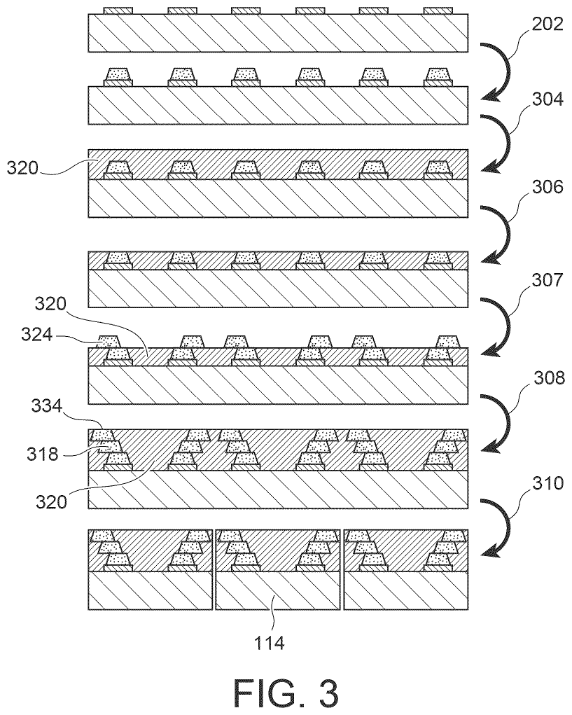

FIG. 3 illustrates a chip package device manufacturing method according to an embodiment.

The example of FIG. 3 comprises a first step similar to step 202 of the example of FIG. 2.

In a step 304, posterior to step 202, an insulating layer 320 of resin, polymer, molding material, or a mask, is formed onto the wafer with a thickness greater or equal to the first alloy amount height.

In a further step 306, the thickness of the layer 320 is grinded or polished until being for example flush with the first alloy amounts top surface.

In a further step 307, second alloy amounts 324 are formed, for example in a same way as step 204, for example not aligned with the first alloy amounts, but horizontally shifted in a manner that the first and second alloy amounts are electrically in contact.

In a further step 308, a second layer, for example of the same material as the material of layer 320, is formed onto the first layer 320 and brought flush to a top surface of the second alloy amounts 324. Third alloy amounts 334 are then formed for example in a same way as step 204, for example not aligned with the second alloy amounts, but horizontally shifted in a manner that the second and third alloy amounts are electrically in contact. Afterwards, a third layer, for example of the same material as the material of layer 320, is formed onto the second layer and brought flush to a top surface of the third alloy amounts 334. This method allows to obtain pillars made of the first, second and third alloy amount which have their longitudinal extension describing an angle between 15° and 80°, or between 100° and 165° for example, as compared to the surface of the chip or the pads 110. In another example, a flat redistribution layer (RDL) can be achieved. In other words, the pillars describe an oblique or inclined orientation as compared to the chip or pad top surface. A redistribution layer is thus formed and can be used to connect the packaged chip device to a substrate which has connection pads having a different pitch as compared to the pitch of the connection pads 110 of the chip 114.

In a non-illustrated step, the insulating material 320 surrounding the pillars 108 can be removed totally or partially.

In a further step 310, the chips 114 are singulated.

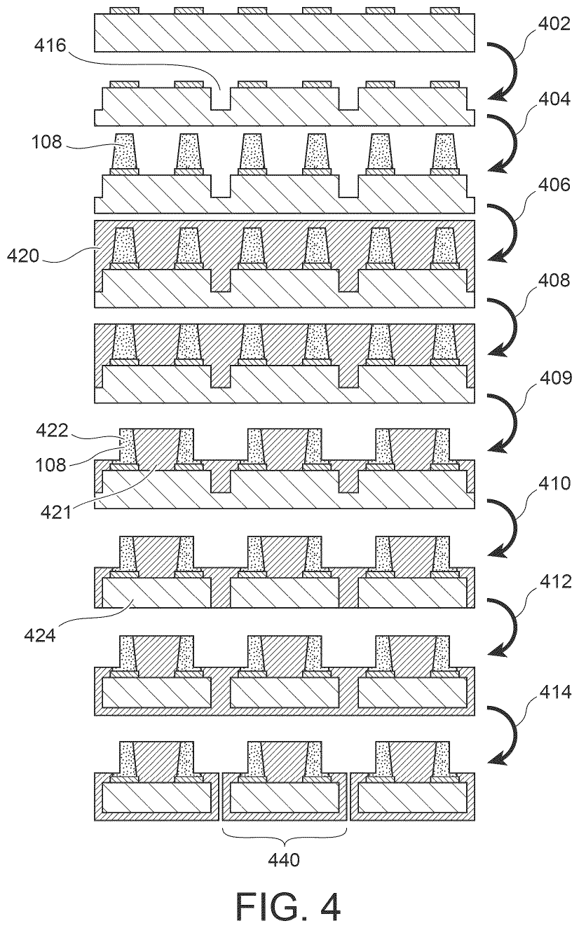

FIG. 4 illustrates a chip package device manufacturing method according to an embodiment.

In a step 402, a substrate, comprising chips having their connecting pads oriented toward the top, is machined to obtain grooves 416 between each chip. The grooves 416 are starting from the top substrate surface and are formed through part of the substrate thickness but are not drilled or cut through all the thickness of the substrate.

In a further step 404, pillars 108 are formed on the connecting pads for example in the same way as for steps 202 to 210. In an example, step 402 is performed after step 404.

In a further step 406, an insulating material such as a resin, a polymer or a molding material 420 is deposited on the top surface of the substrate such that the grooves 416 are filled up as well as the spaces 421 between the pillars 108.

In a further step 408, the material 420 is planarized, for example by grinding or polishing its top surface until its surface is flush with the pillars apex.

In a further step 409, the insulating material 420 is removed, by any mechanical or chemical or etching method, from all or part of the lateral surfaces 422 of the respective pillars, of each chip, which are facing outwards.

In an example, the lateral surfaces 422 of the respective pillars facing outwards, for each chip, are partially grinded or sawed. In this case, the insulating material is still present in the region 421 between the pillars of each chip but it is removed from the outward facing lateral surfaces 422 of the pillars which are located outwards on each chip. In an example, a part of the outward facing surfaces is removed until the respective connecting pads are exposed. In another example, a part of the outward facing surfaces 422 is removed but the respective connecting pads 110 are not exposed.

The step 409 allows the creation of flanks in the pillars which are more or less vertical for example. These flanks ease the formation of a meniscus of solder when the chips are flipped and soldered to a substrate.

In a further optional step 410, the surface 424 of the substrate facing down, also called backside, is grinded until the grooves 416, which are filled up with insulating material, become accessible from this backside 424.

In a further optional step 412, an insulating material, for example the same or a different material as the material 420, is formed on the backside 424 by lamination for example.

In a further step 414, the chips are singulated at the grooves 416, to divide the insulating material filling up the grooves in such way that the insulating material surrounds each side of the singulated chips except the lateral outward facing flanks of the pillars which are arranged outwardly for each chip. The obtained single chips 440 are afterwards optionally soldered to another circuit via a pick and place process.

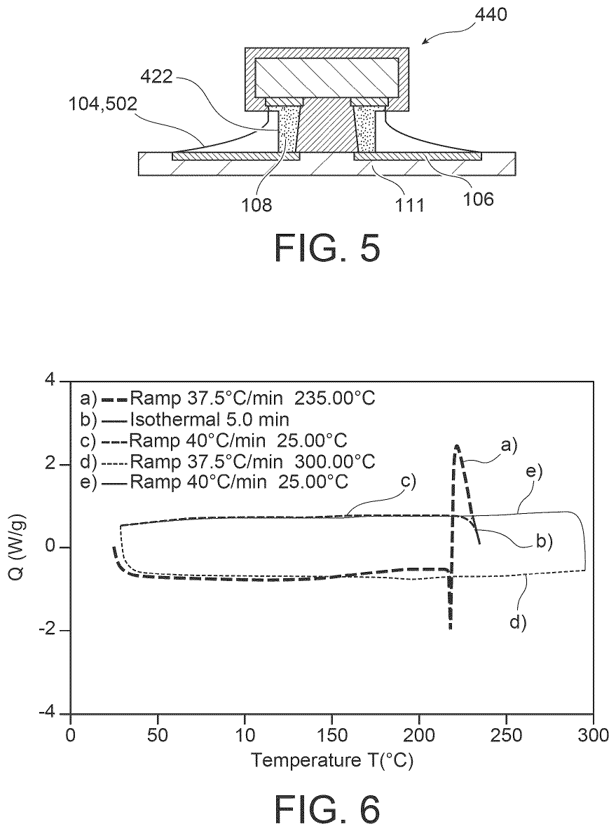

FIG. 5 illustrates a chip package device assembly according to an embodiment.

In the represented example, the chips 440, for example obtained as in step 414 of the previous FIG. 4, is flipped for example with a pick and place step and soldered to the connection pads 106 of a circuit for example similar to circuit 111. The pads 106 extend for example more widely than the chip 424 to ease the formation of a solder meniscus 502.

In FIG. 5, the apex and the sawed, or grinded, surfaces 422 of the pillars 108 are soldered to the respective connection pads 106 with the solder 104 which forms, when the temperature is above its melting temperature, a meniscus 502 between the connection pads 106 and the lateral surface 422. The meniscus shape obtained extends, in a top view, more widely than the chip 440 width. An automatic optical inspection can thus be operated from the top, or with an angle, to verify the presence of the meniscus 502 by light reflection. The presence of the meniscus is an indication that the chip package device, for example a flip-chip or leadless package, is well soldered to the pads 106 of the printed circuit 111.

FIG. 6 illustrates a heat flow graph versus temperature. In the represented example, the heat flow is normalized.

More particularly, the example of FIG. 6 shows how the alloy can be formed from a mix for example of Sn and Cu particles in a flux vehicle. At room temperature the mix is pasty.

In a step a) a temperature ramp, of for example between 1° and 50° C./min, preferably 37.5° C./min, is applied to the mix until reaching 235° C. for example. In the represented example, the heat flow is stable at around −0.6 up to about 218.4° C. Then the heat flow exhibits a drop up to −2 which corresponds to the melting temperature of the first element, here Sn, which wets the second element, here Cu. This drop is then followed by a rapid increase, up to 2, and with again a less sharp drop until reaching 235° C. This behavior is the signature of an interdiffusion of the first and second elements leading to the intermetallic alloy formation.

In a further step b), the temperature is maintained stable for example for 5 minutes in order to improve the crystallinity of the alloy.

In a further step c), the temperature is lowered at a rate between −5 and −50° C./min, for example at −40° C./min, until reaching room temperature. During step c), the heat flow remains stable at around 0.5. At this stage, the alloy is already formed. As it is in a solid state, its shape remains also strong enough to withstand pick and place operations or to allow the storage of the chip package device.

In a further step d), the temperature ramp of, for example between 1° and 50° C./min, for example 40° C./min, is applied to the mix until reaching 300° C. for example. In the example, the heat flow remains stable at around −0.6 up to the temperature of 300° C. It shows that no structure change is this time occurring, that the alloy formed is not melting and that interdiffusion is not occurring anymore. The alloy and its global shape remain stable even at temperatures traditionally used for soldering, such as JEDEC defined conditions.

In a further step e), the temperature is lowered at a rate between −5 and −50° C./min, for example at −40° C./min, until reaching room temperature. During step e), the heat flow remains stable at around 0.5.

The chip package devices presented above may be applied in all the fields where the flip-chip, or WLCSP, or module, or leadless devices are traditionally used for. In an example, the chip package devices described here are used for the Internet of Things (IoT), automotive, or for example smartphones.

The device is for example intended for the automotive industry. The electrification of automotive vehicles generates an expanding high level of electronic content in vehicles. The device for example comprises thyristors, rectifiers, high voltage transient-voltage-suppression diodes, modules, etc., to be incorporated in said vehicles. The automatization of driving also generates an expanding high level of electronic content in vehicles.

The device can for example be used in the industrial field. More especially, the device for example aims at being used for the development of green energies or for the electrification of infrastructures, for example for charging stations or for the incorporation of solar energy. The device can also be used in the field of the internet of things and of smart homes. The device is for example intended for being implemented in the power and energy circuits of pieces of equipment.

The device can also be used in the implementation of clouds, 5G networks, data centers and servers.

The device is for example intended for being used in personal electronics, for example in the aim of increasing radio frequency content, in device of 5G connections or more generally in connected devices. The device is for example a smartphone or a part of a network of internet of things. The device is for example connected by 5G, WIFI or ultra-wide band. The device for example includes high speed interfaces, for example with advanced filtering and protection against electromagnetic discharges.

The chip package devices disclosed are for example intended for being used in communication equipment, or in computers and peripherals. For example, the device can be used in 5G infrastructure and dedicated data centers. The devices can also be used in satellites, comprising for example integrated passive devices for radio frequency applications.

The disclosed devices can be typically used in high-frequency and high-power applications such as satellite communications, radar systems, and microwave amplifiers. They may also be used in some specialized personal electronic devices such as high-end audio amplifiers or radio frequency (RF) transmitters.

The disclosed devices are for example intended for being used in LED (Light Emitting Diode) lighting systems for controlling the current and voltage or help to improve the efficiency and performance of LED lighting systems.

Various embodiments and variants have been described. Those skilled in the art will understand that certain features of these embodiments can be combined and other variants will readily occur to those skilled in the art. In particular, the person of the art would be able for example to combine examples of FIGS. 4 and 5. Also, even if in the Figures described, the pillars have a larger base than the width of their apex, the pillars base could be envisaged to have a smaller base as compared to the width of their apex.

Finally, the practical implementation of the embodiments and variants described herein is within the capabilities of those skilled in the art based on the functional description provided hereinabove. In particular, concerning the temperatures of formation of the intermetallic alloy of the pillars, the person of the art will adapt the temperature treatment profiles according to its knowledge.

1. A chip package device comprising:
at least one connection pad on a first surface of a chip;
at least one pillar extending from, and in contact with, the at least one connection pad; and
wherein the at least one pillar being formed in an alloy of a first element and of a second element, a melting temperature of the alloy being greater than a melting temperature of at least one of the first element and the second element and greater than 260° C.

2. The chip package device according to claim 1, wherein a ratio between a longitudinal extension of the at least one pillar over its width is greater than 0.4.

3. The chip package device according to claim 2, wherein the ratio is greater than 1.

4. The chip package device according to claim 2, wherein the longitudinal extension of the at least one pillar describes an angle with an absolute value between 15° and 80° or between 100° and 165° as compared to a surface of the at least one connection pad.

5. The chip package device according to claim 1, wherein a formation of the at least one pillar comprises:
a first step comprising a deposition of a first amount of a first material, formed with particles of the first element and particles of the second element, in contact with the at least one connection pad; and
a second step comprising a temperature treatment configured to form the alloy.

6. The chip package device according to claim 5, wherein the formation of the at least one pillar comprises:
a third step comprising a deposition of a second amount of the first material, in contact with all or parts of a top surface of a temperature treated first amount; and
a fourth step comprising a temperature treatment configured to form the alloy; and
third and fourth steps being repeatable

7. The chip package device according to claim 5, wherein at least first and second steps are performed on a wafer scale.

8. The chip package device according to claim 1, wherein the first element is Sn, and the second element is among Cu, Ag or Au.

9. The chip package device according to claim 1, wherein an insulating material is arranged around all or parts of lateral surfaces of the at least one pillar.

10. The chip package device according to claim 9, wherein the insulating material surrounds all the chip package device.

11. The chip package device according to claim 9, wherein the insulating material is absent on lateral surfaces of the at least one pillar facing outwards.

12. The chip package device according to claim 11, wherein the lateral surfaces of the at least one pillar facing outwards are grinded or cut.

13. The chip package device according to claim 1, wherein the melting temperature of the alloy is greater than a reflow temperature profile defined by Joint Electron Device Engineering Council (JEDEC).

14. A circuit assembly comprising:
the chip package device according to claim 11;
a printed circuit board comprising at least one connection pad whose surface imprint as seen in top view is larger than the chip; and
a solder material, having a melting temperature inferior to 260° C., and forming a meniscus between a lateral surface of the at least one pillar facing outwards and the at least one connection pad of the printed circuit board.

15. A method of using a chip package device according to claim 1 comprising:
soldering the at least one pillar to at least one connection pad of a printed circuit board by using a solder material having a melting temperature inferior to 260° C.

16. A method of manufacturing a chip package device comprising:
forming a chip of the chip package device, the chip having at least one connection pad on a first surface;
forming at least one pillar extending from, and in contact with, the at least one connection pad, and formed in an alloy of a first element and of a second element; and
wherein a melting temperature of the alloy being greater than a melting temperature of at least one of the first element and second element and greater than 260° C.

17. The method according to claim 16, wherein a ratio between a longitudinal extension of the at least one pillar over its width is greater than 0.4.

18. The method according to claim 17, wherein the ratio is greater than 1.

19. The method according to claim 17, wherein the longitudinal extension of the at least one pillar describes an angle with an absolute value between 15° and 80° or between 100° and 165° as compared to a surface of the at least one connection pad.

20. The method according to claim 16, wherein a formation of the at least one pillar comprises:
a first step comprising a deposition of a first amount of a first material, formed with particles of the first element and particles of the second element, in contact with the at least one connection pad; and
a second step comprising a temperature treatment configured to form the alloy.
